(19) United States
(12) Patent Application Publication
(10) Pub. No.: US 2016/0307692 A1
(43) Pub. Date: Oct. 20, 2016

(54) SELF-LEADED INDUCTIVE DEVICE AND METHODS

(71) Applicant: PULSE ELECTRONICS, INC., San Diego, CA (US)

(72) Inventors: Shuizhen Zhou, Zhuhai City (CN); Shuhui Chen, Hengnan County (CN); Qian Chen, Changsha City (CN)

(21) Appl. No.: 15/131,994

(22) Filed: Apr. 18, 2016

Related U.S. Application Data
(60) Provisional application No. 62/148,641, filed on Apr. 16, 2015.

(51) Int. Cl. H01F 27/28; H01F 27/32; H02M 5/293; H05K 3/34; H02M 5/10; H01F 27/29; H05K 3/30

(52) U.S. Cl. CPC H01F 27/2828; H01F 27/292; H01F 27/325; H05K 3/303; H05K 3/3426; H02M 5/10; H02M 5/293

(57) ABSTRACT

Self-leaded inductive devices and methods of manufacture and use. In one embodiment, the inductive device includes a winding, a first shaped core piece, and a second shaped core piece. The winding is composed of one or more turns and is sized so as to fit around a central spindle element located on the core combination. The windings are preferably round in cross-section and have sufficient thickness so as to retain the shape of the interface portions of the winding so as to provide adequate co-planarity for surface mounting applications. The interface portions of the winding may include for example U-shaped leads, L-shaped leads or wave-shaped leads, and may optionally be formed so as to have a rectangular cross section at the interface portions of the otherwise round winding. Methods of manufacture and use are also disclosed.

### PRIORITY

This application claims the benefit of priority to U.S. Provisional Patent Application Ser. No. 62/148,641 of the same title filed Apr. 16, 2015, which is incorporated herein by reference in its entirety.

### COPYRIGHT

A portion of the disclosure contains material that is subject to copyright protection. The copyright owner has no objection to the facsimile reproduction by anyone of the patent document or the patent disclosure, as it appears in the Patent and Trademark Office patent files or records, but otherwise reserves all copyright rights whatsoever.

### 1. TECHNOLOGICAL FIELD

The present disclosure relates generally to inductive devices for use in electronic devices, and more particularly in one exemplary aspect to a self-leaded inductive device, host apparatus in which one or more of the devices is used, and methods of manufacture and use.

### 2. DESCRIPTION OF RELATED TECHNOLOGY

As is well known in the art, inductive components are electronic devices which provide the property of inductance (i.e., storage of energy in a magnetic field) within an alternating current circuit. Inductors are one well-known type of inductive device, and are formed typically using one or more coils or windings which may or may not be wrapped around a magnetically permeable core. So-called “dual winding” inductors utilize two windings wrapped around a common core.

Transformers are another type of inductive component that are used to transfer energy from one alternating current (AC) circuit to another by magnetic coupling. Generally, transformers are formed by winding two or more wires around a ferrous core. One wire acts as a primary winding and conductively couples energy to and from a first circuit. Another wire, also wound around the core so as to be magnetically coupled with the first wire, acts as a secondary winding and conductively couples energy to and from a second circuit. AC energy applied to the primary windings causes AC energy in the secondary windings and vice versa. A transformer may be used to transform between voltage magnitudes and current magnitudes, to create a phase shift, and to transform between impedance levels. Typically, the costs for manufacturing these inductive components are strong considerations for the purchasers of these devices.

Accordingly, there is a need for an improved electronic device, and a method of manufacturing the device, that minimizes the cost for manufacturing these devices. Ideally, such an improved electronic device does not require use of a bobbin. Such an improved device would ideally utilize existing and well understood technologies in place of a bobbin in order to simplify the manufacturing process and further reduce cost, yet still maintain the desirable electrical and physical properties of its bobbined counterpart.

Furthermore, for certain applications, it would also be highly desirable to enable the customer or user to mount these inductive components in alternate geometries, such as for example over other board-mounted electronic components, such as might be desired in high density applications.

### SUMMARY

The present disclosure satisfies the foregoing needs by providing, inter alia, a self-leaded inductive device, host apparatus, and methods of manufacture and use.

In a first aspect, a self-leaded inductive device is disclosed. In one embodiment, the self-leaded inductive device includes two or more core component portions and a conductive winding having a self-leaded interface portion. At least a portion of the conductive winding is disposed directly about a spindle element associated with the two or more core component portions. The conductive winding has a sufficient thickness so as to provide an adequate co-planarity for a surface mount application.

In one variant, the adequate co-planarity is less than or equal to 0.004 inches.

In another variant, the self-leaded interface portion includes a U-formed lead.

In yet another variant, the self-leaded interface portion includes an L-formed lead.

In yet another variant, the self-leaded interface portion includes a wave-formed lead.

In yet another variant, at least a portion of the conductive winding has a circular cross-sectional area and the self-leaded interface portion is formed so as to include a rectangular cross-sectional area.

In a second aspect, an electronic device (e.g., host) that incorporates the aforementioned self-leaded inductive device is disclosed. In one embodiment, the electronic device is a high density power supply apparatus that includes a printed circuit board; a plurality of power stage electronic components; and a self-leaded inductive device. The self-leaded inductive device includes two or more core component portions; and a conductive winding having a self-leaded interface portion, with the conductive winding having a sufficient thickness so as to provide an adequate co-planarity for a surface mount application. The plurality of power stage electronic components and the self-leaded inductive device are secured to the printed circuit board.

In one variant, at least a portion of the plurality of power stage electronic components is secured to the printed circuit board underneath the self-leaded inductive device.

In another variant, the plurality of power stage electronic components includes a field-effect transistor (FET), a driver component, and a controller component.

In yet another variant, the self-leaded interface portion comprises a U-formed lead.

In yet another variant, the self-leaded interface portion includes an L-formed lead.

In yet another variant, the self-leaded interface portion includes a wave-formed lead.

In yet another variant, at least a portion of the conductive winding has a circular cross-sectional area and the self-leaded interface portion is formed so as to include a rectangular cross-sectional area.

In a third aspect, methods of using the aforementioned self-leaded inductive devices are disclosed. In one embodiment, the method includes procuring the self-leaded inductive device, the self-leaded inductive device having a conductive winding consisting of a self-leaded interface portion and a winding portion; acquiring an electronic component; mounting the electronic component to a printed circuit board; mounting the self-leaded inductive device over the electronic component mounted to the printed circuit board; and securing the self-leaded inductive device and the electronic component to the printed circuit board.

In one variant, the act of securing further includes utilizing a solder-reflow process.

In another variant, the method further includes inspecting the self-leaded interface portion to ensure an adequate co-planarity dimension for the solder-reflow process.

In a fourth aspect, methods of manufacturing the aforementioned self-leaded inductive devices are disclosed.

Further features of the present disclosure, its nature and various advantages will be more apparent from the accompanying drawings and the following detailed description.

### BRIEF DESCRIPTION OF THE DRAWINGS

The features, objectives, and advantages of the disclosure will become more apparent from the detailed description set forth below when taken in conjunction with the drawings, wherein:

FIG. 1A is a perspective exploded view illustrating one embodiment of a self-leaded inductive device having U-formed leads configured in accordance with the principles of the present disclosure.

FIG. 1B is a perspective view of a round wire coil with U-formed leads for use in the self-leaded inductive device of FIG. 1A configured in accordance with the principles of the present disclosure.

FIG. 1C is a front plan view of the self-leaded inductive device of FIG. 1A configured in accordance with the principles of the present disclosure.

FIG. 1D is a perspective view of the assembled self-leaded inductive device of FIG. 1A configured in accordance with the principles of the present disclosure.

FIG. 2A is a perspective exploded view illustrating one embodiment of a self-leaded inductive device having punched U-formed leads configured in accordance with the principles of the present disclosure.

FIG. 2B is a perspective view of a round wire coil with punched U-formed leads for use in the self-leaded inductive device of FIG. 2A configured in accordance with the principles of the present disclosure.

FIG. 2C is a front plan view of the self-leaded inductive device of FIG. 2A configured in accordance with the principles of the present disclosure.

FIG. 2D is a perspective view of the assembled self-leaded inductive device of FIG. 2A configured in accordance with the principles of the present disclosure.

FIG. 3A is a perspective exploded view illustrating one embodiment of a self-leaded inductive device having L-formed leads configured in accordance with the principles of the present disclosure.

FIG. 3B is a perspective view of a round wire coil with L-formed leads for use in the self-leaded inductive device of FIG. 3A configured in accordance with the principles of the present disclosure.

FIG. 3C is a front plan view of the self-leaded inductive device of FIG. 3A configured in accordance with the principles of the present disclosure.

FIG. 3D is a perspective view of the assembled self-leaded inductive device of FIG. 3A configured in accordance with the principles of the present disclosure.

FIG. 4A is a perspective exploded view illustrating one embodiment of a self-leaded inductive device having punched L-formed leads configured in accordance with the principles of the present disclosure.

FIG. 4B is a perspective view of a round wire coil with punched L-formed leads for use in the self-leaded inductive device of FIG. 4A configured in accordance with the principles of the present disclosure.

FIG. 4C is a front plan view of the self-leaded inductive device of FIG. 4A configured in accordance with the principles of the present disclosure.

FIG. 4D is a perspective view of the assembled self-leaded inductive device of FIG. 4A configured in accordance with the principles of the present disclosure.

FIG. 5A is a perspective exploded view illustrating one embodiment of a self-leaded inductive device having wave formed leads configured in accordance with the principles of the present disclosure.

FIG. 5B is a perspective view of a round wire coil with wave formed leads for use in the self-leaded inductive device of FIG. 5A configured in accordance with the principles of the present disclosure.

FIG. 5C is a front plan view of the self-leaded inductive device of FIG. 5A configured in accordance with the principles of the present disclosure.

FIG. 5D is a perspective view of the assembled self-leaded inductive device of FIG. 5A configured in accordance with the principles of the present disclosure.

FIG. 6A is a perspective exploded view illustrating one embodiment of a self-leaded inductive device having punched wave formed leads configured in accordance with the principles of the present disclosure.

FIG. 6B is a perspective view of a round wire coil with punched wave formed leads for use in the self-leaded inductive device of FIG. 6A configured in accordance with the principles of the present disclosure.

FIG. 6C is a front plan view of the self-leaded inductive device of FIG. 6A configured in accordance with the principles of the present disclosure.

FIG. 6D is a perspective view of the assembled self-leaded inductive device of FIG. 6A configured in accordance with the principles of the present disclosure.

FIG. 7A is a perspective view of an F-I core combination for use with the self-leaded inductive devices of FIGS. 1A-6D configured in accordance with the principles of the present disclosure.

FIG. 7B is a perspective view of a P-I core combination for use with the self-leaded inductive devices of FIGS. 1A-6D configured in accordance with the principles of the present disclosure.

All Figures disclosed herein are © Copyright 2014-2015 Pulse Electronics, Inc. All rights reserved.

### DETAILED DESCRIPTION

Reference is now made to the drawings, wherein like numerals refer to like parts throughout.

As used herein, the terms “board” and “substrate” refer generally and without limitation to any substantially planar or curved surface or component upon which other components can be disposed. For example, a substrate may comprise a single or multi-layered printed circuit board (e.g., FR4), a semi-conductive die or wafer, or even a surface of a housing or other device component, and may be substantially rigid or alternatively at least somewhat flexible.

As used herein, the terms “electrical component” and “electronic component” are used interchangeably and refer to components adapted to provide some electrical and/or signal conditioning function, including without limitation inductive reactors (“choke coils”), transformers, filters, transistors, gapped core toroids, inductors (coupled or otherwise), capacitors, resistors, operational amplifiers, and diodes, whether discrete components or integrated circuits, whether alone or in combination.

As used herein, the term “inductive device” refers to any device using or implementing induction including, without limitation, inductors, transformers, and inductive reactors (or “choke coils”.

As used herein, the term “integrated circuit” shall include any type of integrated device of any function, whether single or multiple die, or small or large scale of integration, including without limitation applications specific integrated circuits (ASICs), field programmable gate arrays (FPGAs), digital processors (e.g., DSPs, CISC microprocessors, or RISC processors), memory, and so-called “system-on-a-chip” (SoC) devices.

As used herein, the term “signal conditioning” or “conditioning” shall be understood to include, but not be limited to, signal voltage transformation, filtering and noise mitigation, signal splitting, impedance control and correction, current limiting, and time delay.

As used herein, the terms “top”, “bottom”, “side”, “up”, “down”, “left”, “right”, and the like merely connote a relative position or geometry of one component to another, and in no way connote an absolute frame of reference or any required orientation. For example, a “top” portion of a component may actually reside below a “bottom” portion when the component is mounted to another device (e.g., to the underside of a PCB).

### Overview

In one aspect, an improved inductive device is disclosed. In one embodiment, the inductive device includes a winding; an F-shaped core piece; and an I-shaped core piece, although other core-type combinations such as a PI-type combination are also envisioned. The winding is composed of one or more turns and is sized so as to fit around a central spindle element located on the core combination. The windings are, in one exemplary embodiment, round in cross-section and have sufficient thickness so as to retain the shape of the interface portions of the winding so as to provide adequate co-planarity (e.g., 0.004 inches) for surface mounting applications. The interface portions of the winding may include U-shaped leads, L-shaped leads or wave-shaped leads and may optionally be formed so as to have a rectangular cross section at the interface portions of the otherwise round winding. The inductive device also advantageously includes an open area underneath the inductive device so as to enable the inductive device to be mounted over external electronic components that provide a signal conditioning function for the end application device. For example, in one embodiment, the inductive device is mounted over the power stage electronic components which may include, for example, one or more integrated circuits for a high density power application. Additionally, this open area also enables sufficient airflow underneath the inductive device so as to enable cooling of the inductive device during operation in, for example, high-current power supply applications.

### DETAILED DESCRIPTION OF EXEMPLARY EMBODIMENTS

Detailed descriptions of the various embodiments and variants of the apparatus and methods of the present disclosure are now provided. While primarily discussed in the context of implementation as an inductor having a single winding, the various apparatus and methodologies discussed herein are not so limited. In fact, various embodiments of the apparatus and methodologies described herein are useful in any number of implementations including, for example, transformers. Moreover, the principles of the present disclosure are also applicable to devices that incorporate two or more discrete windings.

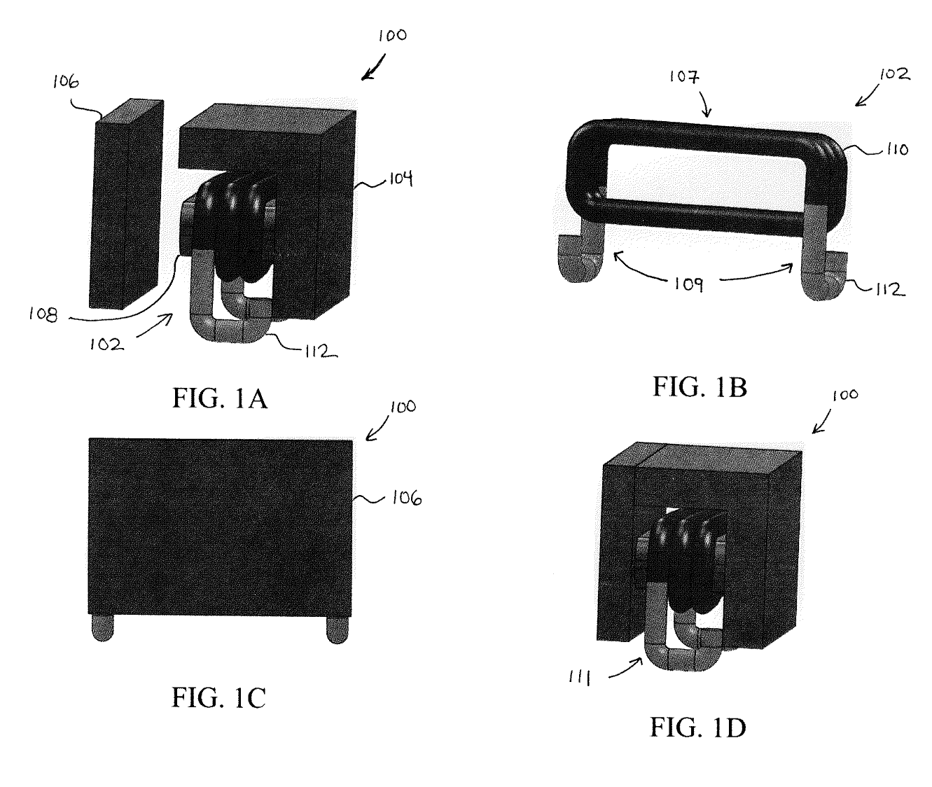

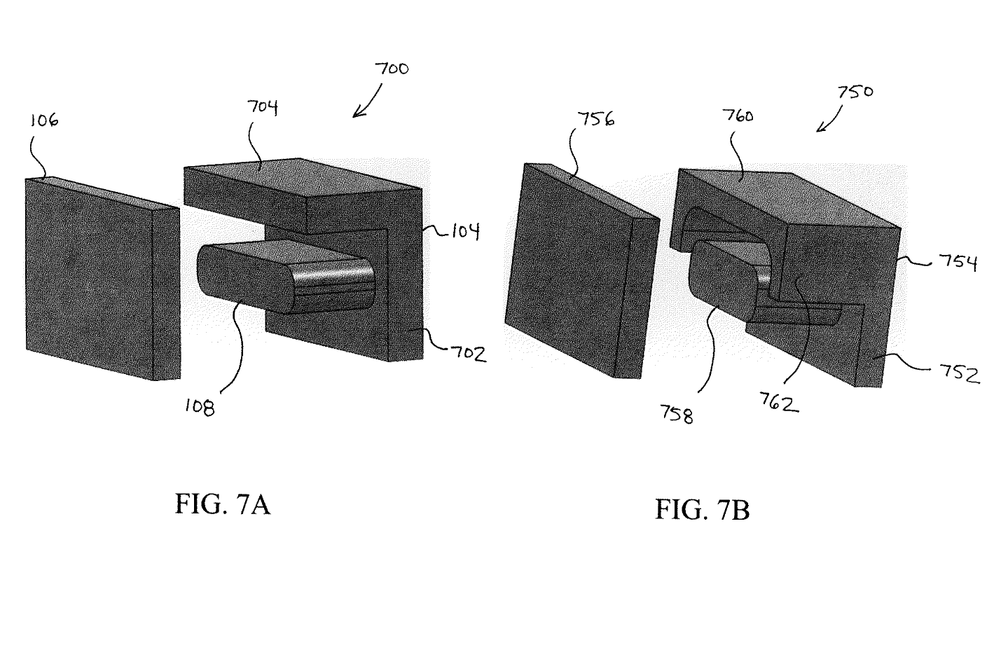

Referring now to FIGS. 1A-1D, a first embodiment of an inductive device 100 is shown and described in detail. The inductive device is composed of three (3) main components which include: (1) a winding 102; (2) an F-shaped core piece 104; and (3) an I-shaped core piece 106. Although the inductive device shown in FIGS. 1A-1D is composed of an F-shaped core piece in combination with an I-shaped core piece (“core combination”), it is readily appreciated that other core shapes can readily be utilized. For example, in one embodiment, the FI core combination can be replaced with a P-shaped core (725, FIG. 7B) in combination with an I-shaped core (756, FIG. 7B). Other core-types including, for example, E-type cores; EFD-type cores; ER-type cores; EP-type cores; and pot-core style cores could also be readily substituted. Moreover, while primarily envisioned as being manufactured from various formulations made from ferrite, other formulations could also readily be substituted including, for example, soft iron; laminated silicon steel; carbonyl iron; and iron powder formulations. The particular material choice chosen will depend upon, for example, the magnetic permeability desired for the end application inductive device. Additionally, while the FI-core combination illustrated in FIG. 1D is shown without the introduction of a gap between the core pieces, various embodiments which contain gaps between the central spindle element 108 located on the F-shaped core piece 104 and the I-shaped core piece 106 are also envisioned. These gaps (not shown) can have various sizes and can be filled with various epoxy compounds; or alternatively can comprise so-called air gaps thereby affecting the underlying magnetic properties of the core combination.

The winding 102 illustrated in FIGS. 1A-1D is composed of multiple turns 110 (i.e., three (3) turns), although more or less turns are also envisioned in alternative embodiments depending upon the particular electrical characteristics of the inductive device desired. The turns 110 of the winding 102 are sized so as to fit around the central spindle element 108 located on the F-shaped core piece 104. The interface portion 112 of the illustrated winding 102 is, in the illustrated embodiment, formed into a U-shaped lead. Moreover, the winding 102 comprises an insulated portion 107 followed by non-insulated portions 109 disposed on either end of the winding. The non-insulated portion 109 can be formed from, for example, a solder dipping operation on the winding 102 that takes place either before or after the turns 110 for the winding are formed. The winding 102 will also have sufficient thickness so as to retain the shape of the windings and interface portions 112 of the winding after they have been formed so as to provide adequate co-planarity (e.g., 0.004 inches) for surface mounting applications. As is well understood, adequate co-planarity for a surface mounting application is typically less than the thickness of the solder paste applied to the substrate. For example, in surface mounting applications in which the solder paste is applied to a printed circuit board with a thickness on the order of 0.010 inches, adequate co-planarity will be less than the thickness of the solder paste so as to ensure a reliable electrical connection during solder reflow processes.

The inductive device also advantageously includes an open area 111 underneath the inductive device so as to enable the inductive device to be mounted over electronic components. For example, in one embodiment, the inductive device is mounted over the power stage for a high density application and these external electronic components can include, for example, a field-effect transistor (FET); a driver; and/or a controller. Additionally, this open area 111 also enables sufficient airflow underneath the inductive device so as to enable cooling of the inductive device during operation in, for example, power supply applications.

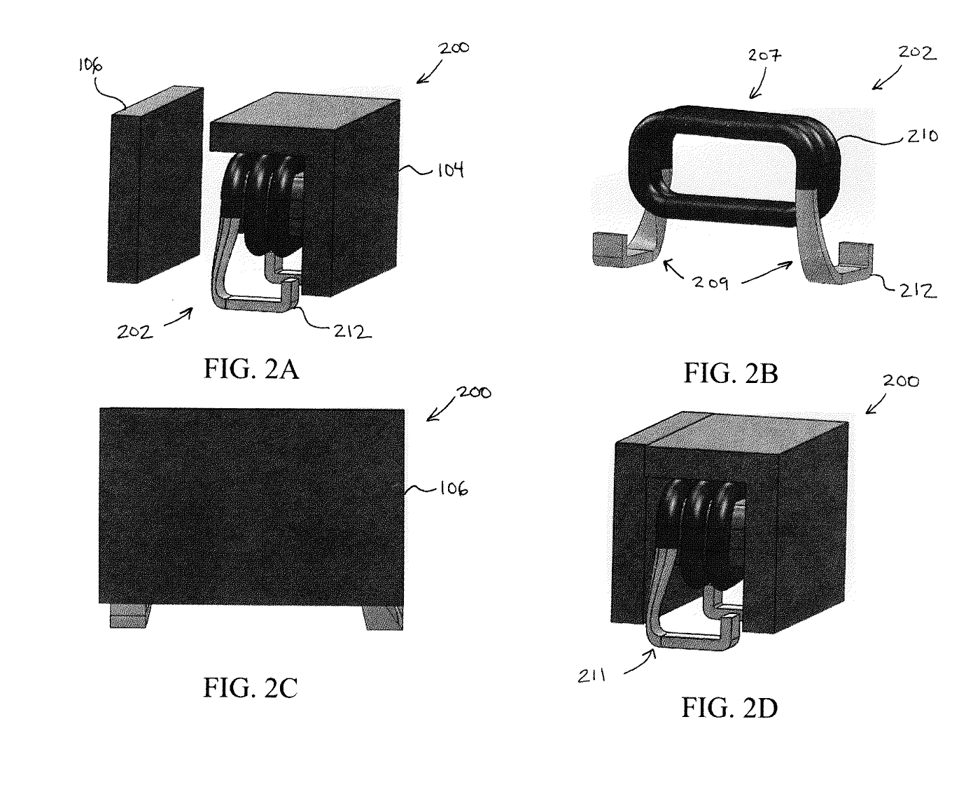

Referring now to FIGS. 2A-2D, an alternative embodiment for an inductive device 200 is shown and described in detail. Similar to the embodiment discussed above with regards to FIGS. 1A-1D, the inductive device is composed of three (3) main components which include: (1) a winding 202; (2) an F-shaped core piece 104; and (3) an I-shaped core piece 106. Again, although the inductive device shown in FIGS. 2A-2D is composed of an F-shaped core piece in combination with an I-shaped core piece, it is readily appreciated that other core shapes can readily be utilized. For example, in one embodiment, the FI core combination can be replaced with a P-shaped core (725, FIG. 7B) in combination with an I-shaped core (756, FIG. 7B). Other core-types including, for example, E-type cores; EFD-type cores; ER-type cores; EP-type cores; and pot-core style cores could also be readily substituted. Moreover, while primarily envisioned as being manufactured from various formulations made from ferrite, other formulations could also readily be substituted including, for example, soft iron; laminated silicon steel; carbonyl iron; and iron powder formulations. The particular material choice chosen will depend upon, for example, the magnetic permeability desired for the end application inductive device. Additionally, while the FI-core combination illustrated in FIG. 2D is shown without the introduction of a gap between the core pieces, various embodiments which contain gaps between the central spindle element located on the F-shaped core piece 104 and the I-shaped core piece 106 are also envisioned. These gaps (not shown) can have various sizes and can be filled with various epoxy compounds; or alternatively can comprise so-called air gaps thereby affecting the underlying magnetic properties of the core combination.

Moreover, the winding 202 illustrated in FIGS. 2A-2D is composed of multiple turns 210 (i.e., three (3) turns), although more or less turns are also envisioned in alternative embodiments depending upon the particular electrical characteristics of the inductive device desired. The turns 210 of the winding 202 are sized so as to fit around the central spindle element located on the F-shaped core piece 104. The interface portion 212 of the illustrated winding 202 is, in the illustrated embodiment, formed into a punched U-shaped lead. In other words, the round wire coil winding is post-formed using, for example, a die which forms the leads into a rectangular cross-section (as opposed to the round cross-section illustrated in FIGS. 1A-1D). Moreover, the winding 202 comprises an insulated portion 207 followed by non-insulated portions 209 disposed on either end of the winding. The non-insulated portion 209 can be formed from, for example, a solder dipping operation on the winding 202 that takes place either before or after the turns 210 for the winding are formed. The winding 202 will also have sufficient thickness so as to retain the shape of the windings and interface portions 212 of the winding after they have been formed so as to provide adequate co-planarity for surface mounting applications.

The inductive device also advantageously includes an open area 211 underneath the inductive device so as to enable the inductive device to be mounted over electronic components. For example, in one embodiment, the inductive device is mounted over the power stage for a high density application and these external electronic components can include, for example, a field-effect transistor (FET); a driver; and/or a controller. Additionally, this open area 211 also enables sufficient airflow underneath the inductive device so as to enable cooling of the inductive device during operation in, for example, power supply applications.

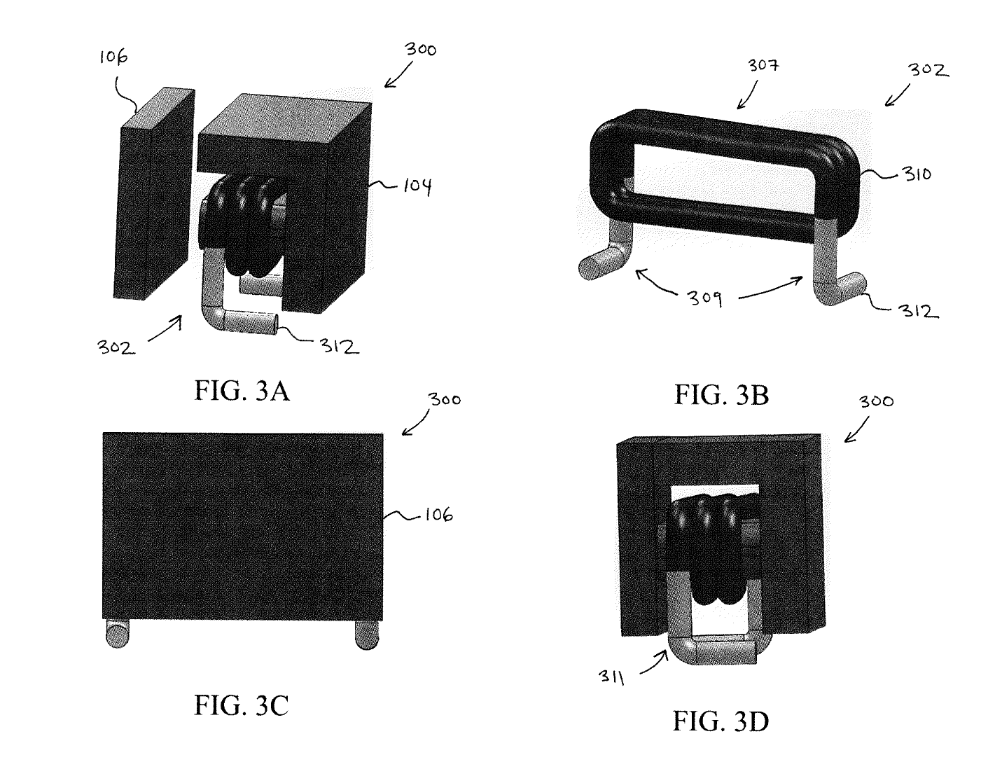

Referring now to FIGS. 3A-3D, an alternative embodiment for an inductive device 300 is shown and described in detail. Similar to the embodiment discussed above with regards to FIGS. 1A-1D, the inductive device is composed of three (3) main components which include: (1) a winding 302; (2) an F-shaped core piece 104; and (3) an I-shaped core piece 106. Again, although the inductive device shown in FIGS. 3A-3D is composed of an F-shaped core piece in combination with an I-shaped core piece, it is readily appreciated that other core shapes can readily be utilized. For example, in one embodiment, the FI core combination can be replaced with a P-shaped core (725, FIG. 7B) in combination with an I-shaped core (756, FIG. 7B). Other core-types including, for example, E-type cores; EFD-type cores; ER-type cores; EP-type cores; and pot-core style cores could also be readily substituted. Moreover, while primarily envisioned as being manufactured from various formulations made from ferrite, other formulations could also readily be substituted including, for example, soft iron; laminated silicon steel; carbonyl iron; and iron powder formulations. The particular material choice chosen will depend upon, for example, the magnetic permeability desired for the end application inductive device. Additionally, while the FI-core combination illustrated in FIG. 3D is shown without the introduction of a gap between the core pieces, various embodiments which contain gaps between the central spindle element located on the F-shaped core piece 104 and the I-shaped core piece 106 are also envisioned. These gaps (not shown) can have various sizes and can be filled with various epoxy compounds; or alternatively can comprise so-called air gaps thereby affecting the underlying magnetic properties of the core combination.

Moreover, the winding 302 illustrated in FIGS. 3A-3D is composed of multiple turns 310 (i.e., three (3) turns), although more or less turns are also envisioned in alternative embodiments depending upon the particular electrical characteristics of the inductive device desired. The turns 310 of the winding 302 are sized so as to fit around the central spindle element located on the F-shaped core piece 104. The interface portion 312 of the illustrated winding 302 is, in the illustrated embodiment, formed into an L-shaped lead. Moreover, the winding 302 comprises an insulated portion 307 followed by non-insulated portions 309 disposed on either end of the winding. The non-insulated portion 309 can be formed from, for example, a solder dipping operation on the winding 302 that takes place either before or after the turns 310 for the winding are formed. The winding 302 will also have sufficient thickness so as to retain the shape of the windings and interface portions 312 of the winding after they have been formed so as to provide adequate co-planarity for surface mounting applications.

The inductive device also advantageously includes an open area 311 underneath the inductive device so as to enable the inductive device to be mounted over electronic components. For example, in one embodiment, the inductive device is mounted over the power stage for a high density application and these external electronic components can include, for example, a field-effect transistor (FET); a driver; and/or a controller. Additionally, this open area 311 also enables sufficient airflow underneath the inductive device so as to enable cooling of the inductive device during operation in, for example, power supply applications.

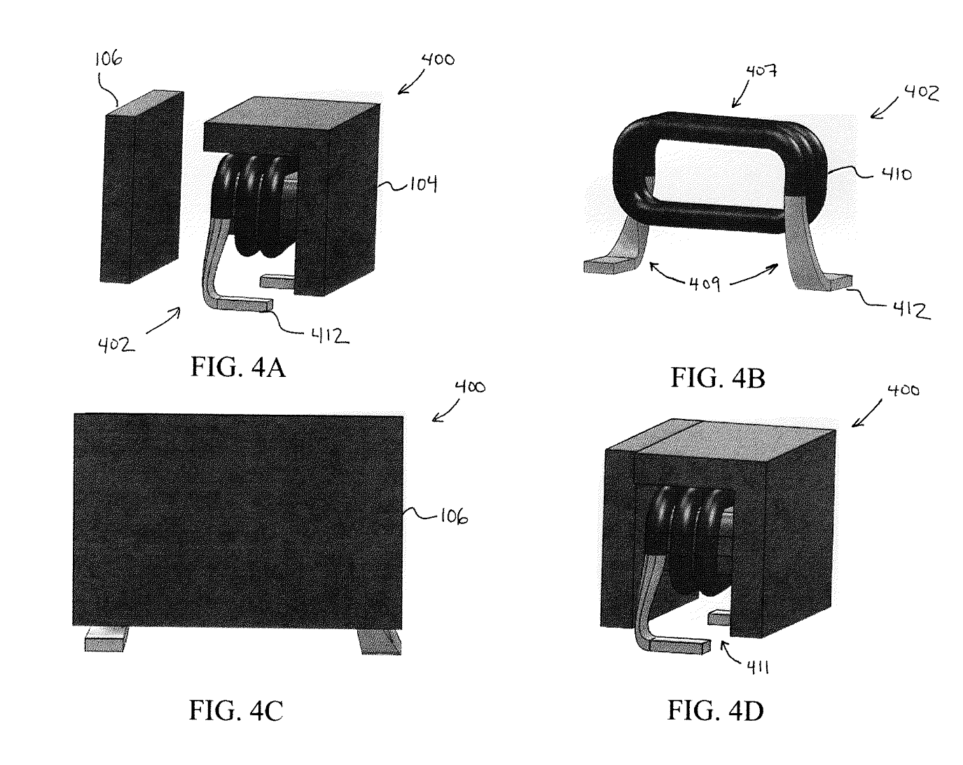

Referring now to FIGS. 4A-4D, an alternative embodiment for an inductive device 400 is shown and described in detail. Similar to the embodiment discussed above with regards to FIGS. 1A-1D, the inductive device is composed of three (3) main components which include: (1) a winding 402; (2) an F-shaped core piece 104; and (3) an I-shaped core piece 106. Again, although the inductive device shown in FIGS. 4A-4D is composed of an F-shaped core piece in combination with an I-shaped core piece, it is readily appreciated that other core shapes can readily be utilized. For example, in one embodiment, the FI core combination can be replaced with a P-shaped core (725, FIG. 7B) in combination with an I-shaped core (756, FIG. 7B). Other core-types including, for example, E-type cores; EFD-type cores; ER-type cores; EP-type cores; and pot-core style cores could also be readily substituted. Moreover, while primarily envisioned as being manufactured from various formulations made from ferrite, other formulations could also readily be substituted including, for example, soft iron; laminated silicon steel; carbonyl iron; and iron powder formulations. The particular material choice chosen will depend upon, for example, the magnetic permeability desired for the end application inductive device. Additionally, while the FI-core combination illustrated in FIG. 4D is shown without the introduction of a gap between the core pieces, various embodiments which contain gaps between the central spindle element located on the F-shaped core piece 104 and the I-shaped core piece 106 are also envisioned. These gaps (not shown) can have various sizes and can be filled with various epoxy compounds; or alternatively can comprise so-called air gaps thereby affecting the underlying magnetic properties of the core combination.

Moreover, the winding 402 illustrated in FIGS. 4A-4D is composed of multiple turns 410 (i.e., three (3) turns), although more or less turns are also envisioned in alternative embodiments depending upon the particular electrical characteristics of the inductive device desired. The turns 410 of the winding 402 are sized so as to fit around the central spindle element located on the F-shaped core piece 104. The interface portion 412 of the illustrated winding 402 is, in the illustrated embodiment, formed into a punched L-shaped lead. In other words, the round wire coil winding is post-formed using, for example, a die which forms the leads into a rectangular cross-section (as opposed to the round cross-section illustrated in FIGS. 3A-3D). Moreover, the winding 402 comprises an insulated portion 407 followed by non-insulated portions 409 disposed on either end of the winding. The non-insulated portion 409 can be formed from, for example, a solder dipping operation on the winding 402 that takes place either before or after the turns 410 for the winding are formed. The winding 402 will also have sufficient thickness so as to retain the shape of the windings and interface portions 412 of the winding after they have been formed so as to provide adequate co-planarity for surface mounting applications.

The inductive device also advantageously includes an open area 411 underneath the inductive device so as to enable the inductive device to be mounted over electronic components. For example, in one embodiment, the inductive device is mounted over the power stage for a high density application and these external electronic components can include, for example, a field-effect transistor (FET); a driver; and/or a controller. Additionally, this open area 411 also enables sufficient airflow underneath the inductive device so as to enable cooling of the inductive device during operation in, for example, power supply applications.

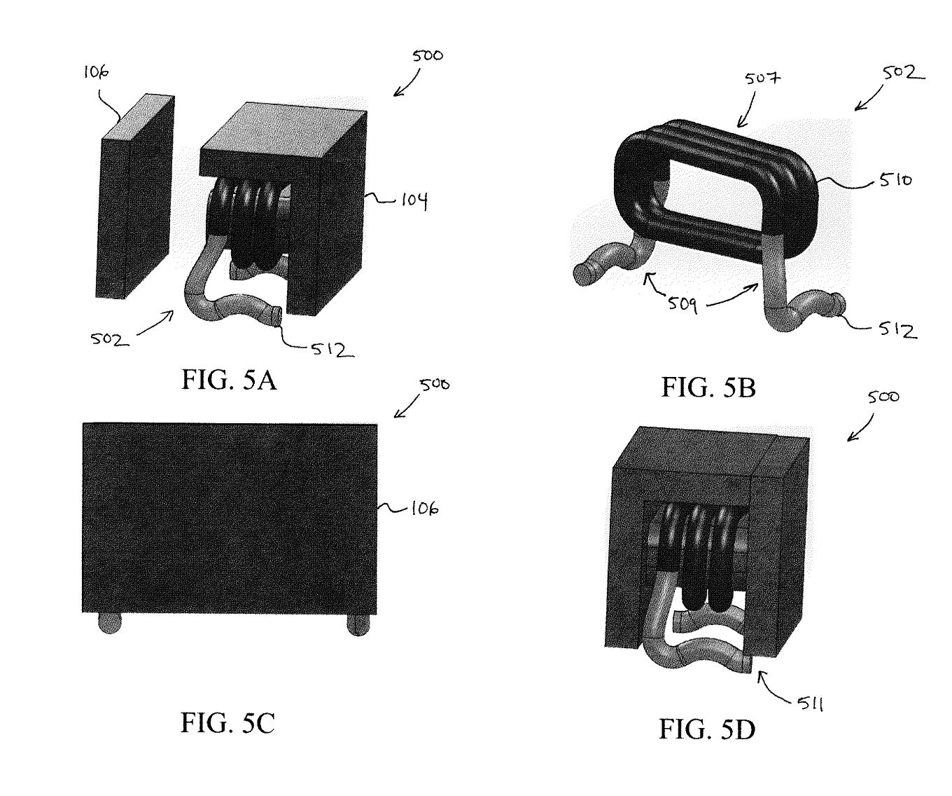

Referring now to FIGS. 5A-5D, an alternative embodiment for an inductive device 500 is shown and described in detail. Similar to the embodiment discussed above with regards to FIGS. 1A-1D, the inductive device is composed of three (3) main components which include: (1) a winding 502; (2) an F-shaped core piece 104; and (3) an I-shaped core piece 106. Again, although the inductive device shown in FIGS. 5A-5D is composed of an F-shaped core piece in combination with an I-shaped core piece, it is readily appreciated that other core shapes can readily be utilized. For example, in one embodiment, the FI core combination can be replaced with a P-shaped core (725, FIG. 7B) in combination with an I-shaped core (756, FIG. 7B). Other core-types including, for example, E-type cores; EFD-type cores; ER-type cores; EP-type cores; and pot-core style cores could also be readily substituted. Moreover, while primarily envisioned as being manufactured from various formulations made from ferrite, other formulations could also readily be substituted including, for example, soft iron; laminated silicon steel; carbonyl iron; and iron powder formulations. The particular material choice chosen will depend upon, for example, the magnetic permeability desired for the end application inductive device. Additionally, while the FI-core combination illustrated in FIG. 5D is shown without the introduction of a gap between the core pieces, various embodiments which contain gaps between the central spindle element located on the F-shaped core piece 104 and the I-shaped core piece 106 are also envisioned. These gaps (not shown) can have various sizes and can be filled with various epoxy compounds; or alternatively can comprise so-called air gaps thereby affecting the underlying magnetic properties of the core combination.

Moreover, the winding 502 illustrated in FIGS. 5A-5D is composed of multiple turns 510 (i.e., three (3) turns), although more or less turns are also envisioned in alternative embodiments depending upon the particular electrical characteristics of the inductive device desired. The turns 510 of the winding 502 are sized so as to fit around the central spindle element located on the F-shaped core piece 104. The interface portion 512 of the illustrated winding 502 is, in the illustrated embodiment, formed into a wave-shaped lead. Moreover, the winding 502 comprises an insulated portion 507 followed by non-insulated portions 509 disposed on either end of the winding. The non-insulated portion 509 can be formed from, for example, a solder dipping operation on the winding 502 that takes place either before or after the turns 510 for the winding are formed. The winding 502 will also have sufficient thickness so as to retain the shape of the windings and interface portions 512 of the winding after they have been formed so as to provide adequate co-planarity for surface mounting applications.

The inductive device also advantageously includes an open area 511 underneath the inductive device so as to enable the inductive device to be mounted over electronic components. For example, in one embodiment, the inductive device is mounted over the power stage for a high density application and these external electronic components can include, for example, a field-effect transistor (FET); a driver; and/or a controller. Additionally, this open area 511 also enables sufficient airflow underneath the inductive device so as to enable cooling of the inductive device during operation in, for example, power supply applications.

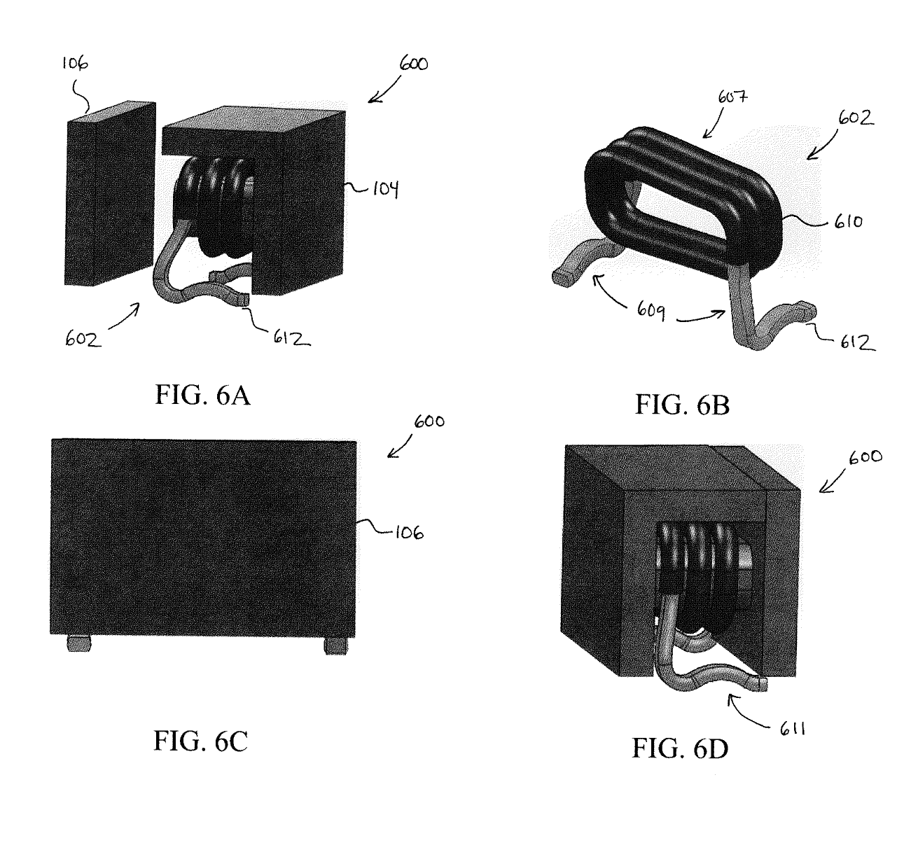

Referring now to FIGS. 6A-6D, an alternative embodiment for an inductive device 600 is shown and described in detail. Similar to the embodiment discussed above with regards to FIGS. 1A-1D, the inductive device is composed of three (3) main components which include: (1) a winding 602; (2) an F-shaped core piece 104; and (3) an I-shaped core piece 106. Again, although the inductive device shown in FIGS. 6A-6D is composed of an F-shaped core piece in combination with an I-shaped core piece, it is readily appreciated that other core shapes can readily be utilized. For example, in one embodiment, the FI core combination can be replaced with a P-shaped core (725, FIG. 7B) in combination with an I-shaped core (756, FIG. 7B). Other core-types including, for example, E-type cores; EFD-type cores; ER-type cores; EP-type cores; and pot-core style cores could also be readily substituted. Moreover, while primarily envisioned as being manufactured from various formulations made from ferrite, other formulations could also readily be substituted including, for example, soft iron; laminated silicon steel; carbonyl iron; and iron powder formulations. The particular material choice chosen will depend upon, for example, the magnetic permeability desired for the end application inductive device. Additionally, while the FI-core combination illustrated in FIG. 6D is shown without the introduction of a gap between the core pieces, various embodiments which contain gaps between the central spindle element located on the F-shaped core piece 104 and the I-shaped core piece 106 are also envisioned. These gaps (not shown) can have various sizes and can be filled with various epoxy compounds; or alternatively can comprise so-called air gaps thereby affecting the underlying magnetic properties of the core combination.

Moreover, the winding 602 illustrated in FIGS. 6A-6D is composed of multiple turns 610 (i.e., three (3) turns), although more or less turns are also envisioned in alternative embodiments depending upon the particular electrical characteristics of the inductive device desired. The turns 610 of the winding 602 are sized so as to fit around the central spindle element located on the F-shaped core piece 104. The interface portion 612 of the illustrated winding 602 is, in the illustrated embodiment, formed into a punched wave-shaped lead. In other words, the round wire coil winding is post-formed using, for example, a die which forms the leads into a rectangular cross-section (as opposed to the round cross-section illustrated in FIGS. 5A-5D). Moreover, the winding 602 comprises an insulated portion 607 followed by non-insulated portions 609 disposed on either end of the winding. The non-insulated portion 609 can be formed from, for example, a solder dipping operation on the winding 602 that takes place either before or after the turns 610 for the winding are formed. The winding 602 will also have sufficient thickness so as to retain the shape of the windings and interface portions 612 of the winding after they have been formed so as to provide adequate co-planarity for surface mounting applications.

The inductive device also advantageously includes an open area 611 underneath the inductive device so as to enable the inductive device to be mounted over electronic components. For example, in one embodiment, the inductive device is mounted over the power stage for a high density application and these external electronic components can include, for example, a field-effect transistor (FET); a driver; and/or a controller. Additionally, this open area 611 also enables sufficient airflow underneath the inductive device so as to enable cooling of the inductive device during operation in, for example, power supply applications.

Referring now to FIG. 7A, an exemplary FI-core combination 700 is shown and described in detail. The FI-core combination includes an F-shaped core piece 104 as well as an I-shaped core piece 106. The I-shaped core piece 106 is rectangular in shape having a width and a height, with the width being, in the illustrated embodiment, larger in dimension than the height. The F-shaped core piece 104 includes a central spindle element 108 that extends from the vertical portion 702 of the F-shaped core. The F-shaped core piece 104 also includes a horizontal portion 704 that extends orthogonally from the vertical portion 702. In one exemplary embodiment, the F-shaped core piece has a width that is substantially the same as the width for the I-shaped core piece as well a height that is substantially the same as the height for the I-shaped core piece. Moreover, the central spindle element 108 in combination with the horizontal portion 704 and the I-shaped core piece 106 is configured to provide a closed magnetic path for the FI-core combination 700 when windings are disposed about the central spindle element.

Referring now to FIG. 7B, an exemplary PI-core combination 750 is shown and described in detail. The PI-core combination includes a P-shaped core piece 754 as well as an I-shaped core piece 756. The I-shaped core piece 756 is rectangular in shape having a width and a height, with the width being, in the illustrated embodiment, larger in dimension than the height. The P-shaped core piece 754 includes a central spindle element 758 that extends from the vertical portion 752 of the P-shaped core. The P-shaped core piece 754 also includes a horizontal portion 760 that extends orthogonally from the vertical portion 752. Moreover, the horizontal portion 760 also includes downwardly extending side portions 762 which, inter alia, increases the amount of cross-sectional area provided for the PI-core combination as compared with an FI-core combination having an identical width and height. In one exemplary embodiment, the P-shaped core piece has a width that is substantially the same as the width for the I-shaped core piece as well a height that is substantially the same as the height for the I-shaped core piece. Moreover, the central spindle element 758 in combination with the horizontal portion 760 and the I-shaped core piece 756 is configured to provide a closed magnetic path for the PI-core combination 750 when windings are disposed about the central spindle element.

It will be recognized that while certain aspects of the disclosure are described in terms of a specific sequence of steps of a method, these descriptions are only illustrative of the broader methods of the present disclosure, and may be modified as required by the particular application. Certain steps may be rendered unnecessary or optional under certain circumstances. Additionally, certain steps or functionality may be added to the disclosed embodiments, or the order of performance of two or more steps permuted. All such variations are considered to be encompassed within the disclosure as discussed and claimed herein.

While the above detailed description has shown, described, and pointed out novel features of the invention as applied to various embodiments, it will be understood that various omissions, substitutions, and changes in the form and details of the device or process illustrated may be made by those skilled in the art without departing from the invention. The foregoing description is of the best mode presently contemplated of carrying out the invention. This description is in no way meant to be limiting, but rather should be taken as illustrative of the general principles of the invention. The scope of the invention should be determined with reference to the claims.

What is claimed is:

1. A self-leaded inductive device, comprising:
two or more core component portions; and
a conductive winding comprised of a self-leaded interface portion, the conductive winding having a sufficient thickness so as to provide an adequate co-planarity for a surface mount application;
wherein at least a portion of the conductive winding is disposed directly about a spindle element associated with the two or more core component portions.

2. The self-leaded inductive device of claim 1, wherein the adequate co-planarity is less than or equal to 0.004 inches.

3. The self-leaded inductive device of claim 2, wherein the self-leaded interface portion comprises a U-formed lead.

4. The self-leaded inductive device of claim 3, wherein the at least the portion of the conductive winding comprises a circular cross-sectional area and the self-leaded interface portion is formed so as to comprise a rectangular cross-sectional area.

5. The self-leaded inductive device of claim 2, wherein the self-leaded interface portion comprises an L-formed lead.

6. The self-leaded inductive device of claim 5, wherein the at least the portion of the conductive winding comprises a circular cross-sectional area and the self-leaded interface portion is formed so as to comprise a rectangular cross-sectional area.

7. The self-leaded inductive device of claim 1, wherein the self-leaded interface portion comprises a wave-formed lead, the wave-formed lead comprising one or more undulations of the conductive winding.

8. The self-leaded inductive device of claim 7, wherein the at least the portion of the conductive winding comprises a circular cross-sectional area and the self-leaded interface portion is formed so as to comprise a rectangular cross-sectional area.

9. A method of using a self-leaded inductive device, comprising:
procuring the self-leaded inductive device, the self-leaded inductive device comprising a conductive winding consisting of a self-leaded interface portion and a winding portion;
acquiring an electronic component;
mounting the electronic component to a printed circuit board;
mounting the self-leaded inductive device over the electronic component mounted to the printed circuit board; and
securing the self-leaded inductive device and the electronic component to the printed circuit board.

10. The method of claim 9, wherein the act of securing further comprises utilizing a solder-reflow process.

11. The method of claim 10, further comprising inspecting the self-leaded interface portion to ensure an adequate co-planarity dimension for the solder-reflow process.

12. A high density power supply apparatus, comprising:
a printed circuit board;
a plurality of power stage electronic components; and
a self-leaded inductive device, comprising:
two or more core component portions; and
a conductive winding comprised of a self-leaded interface portion, the conductive winding having a sufficient thickness so as to provide an adequate co-planarity for a surface mount application;
wherein the plurality of power stage electronic components and the self-leaded inductive device are secured to the printed circuit board.

13. The high density power supply apparatus of claim 12, wherein at least a portion of the plurality of power stage electronic components are secured to the printed circuit board underneath the self-leaded inductive device.

14. The high density power supply apparatus of claim 13, wherein the plurality of power stage electronic components comprises a field-effect transistor (FET), a driver component, and a controller component.

15. The high density power supply apparatus of claim 12, wherein the self-leaded interface portion comprises a U-formed lead.

16. The high density power supply apparatus of claim 15, wherein a winding portion of the conductive winding comprises a circular cross-sectional area and the self-leaded interface portion is formed so as to comprise a rectangular cross-sectional area.

17. The high density power supply apparatus of claim 12, wherein the self-leaded interface portion comprises an L-formed lead.

18. The high density power supply apparatus of claim 17, wherein a winding portion of the conductive winding comprises a circular cross-sectional area and the self-leaded interface portion is formed so as to comprise a rectangular cross-sectional area.

19. The high density power supply apparatus of claim 12, wherein the self-leaded interface portion comprises a wave-formed lead, the wave-formed lead comprising one or more undulations of the conductive winding.

20. The high density power supply apparatus of claim 19, wherein a winding portion of the conductive winding comprises a circular cross-sectional area and the self-leaded interface portion is formed so as to comprise a rectangular cross-sectional area.
